(19) United States
(12) Patent Application Publication
(10) Pub. No.: US 2004/0027154 A1
(43) Pub. Date: Feb. 12, 2004

(54) Nanoelectronic devices

(76) Inventors: Lars I Samuelson, Ynglingagatan Malmo (SE); Honggi Xu, Annehemsvagen Lund (SE); Alfred Forchel, Abstleitenweg Wurzburg (DE); Lukas Worschech, Adelgundenweg Wurzburg (DE)

Correspondence Address: NIXON & VANDERHYE, PC, 1100 N GLEBE ROAD, 8TH FLOOR, ARLINGTON, VA, 22201-4714, US

(21) Appl. No.: 10/363,047

(22) PCT Filed: Sep. 3, 2001
(86) PCT No.: PCT/GB01/03954

(30) Foreign Application Priority Data
Sep. 1, 2000 (GB) 0021506.1
Dec. 7, 2000 (GB) 0029902.4
Mar. 23, 2001 (GB) 0107409.5

(51) Int. Cl. G06F 7/38; H03K 19/173

(52) U.S. Cl. 326/37

(57) ABSTRACT

An electronic device of nanometric dimensions which exhibits non-linear transistor or rectifying action comprises a region (40) fabricated to provide ballistic transport properties for electron flow, with conductance paths (42, 44, 46) having quantum point contacts (40q) formed in region (40), each path having an associated reservoir of electrons, or contact (50), with an electro-chemical potential, and a linear-response conductance which depends on the energy of electrons injected into the path. An alternating voltage Vₗ, Vᵣ, is applied across conductance paths (44,46), and a rectified voltage V_{c} is developed at conductance path (42). Altematively, a constant voltage may be applied to terminal (44), to modulate the characteristics of electron flow through conductance paths (42, 46), in a transistor-like manner. The device may perform a logic AND or OR function, or be used as a frequency multiplier.

The present invention relates to nanoelectronic devices, employing the properties of electrons at small dimensions of the order of nanometers.

By way of background, it is well known that at atomic or molecular dimensions or nanometers (nm), in suitable materials, the transport properties of electrons change remarkably. In order to achieve high electron mobility, without scattering, so that the electrons have a long mean free path, (i.e. the electrons may be regarded as ballistic in their flow paths), it is usual to form what is known as a two-dimensional electron gas (2DEG). One way of achieving this is shown in FIG. 1A, wherein a very thin layer, ≦100 nm, of AlGaAs 10, is formed on a layer 12 some microns thick, of GaAs, having impurities 14. Layer 12 is formed on a substrate 16 of high purity. As shown in FIG. 1B, the energy levels for electrons have a “well” at 18 at the boundary between the layers 10, 12. Electrons from ionised impurities 14 transfer into well 18. In this region, electrons have quantised energy states, along the direction of growth, and a very long mean free path in the plane of the layers, several microns long. This figure is applicable at temperatures close to absolute zero—as the temperature rises, so does the amount of phonon scattering, which reduces the mean free path.

Another structure for achieving 2DEG is shown in FIG. 2A, wherein layers 20, 22 of InP have formed between them a very thin layer 24 of GaInAs, about 20 nm thick. This forms a quantum well device with energy levels as shown in FIG. 2B. In the quantum well region 24 the electrons have long in-plane mean free paths.

The so-called quantum point contact is of interest. A point contact is formed by simply pressing two metal parts together to permit current flow through the point contact thus formed. A quantum point contact is formed as a narrow constriction in a material, through which electrons may flow, the width of the constriction being comparable to the Fermi wavelength of the electrons in the material, and much less than their mean free path. In such a contact, quantum-mechanical effects are exhibited. For example, the quantum point contact shown in FIG. 3A comprises a narrow constriction, or saddle point 32, of the order of 10-100 nm wide between two smooth convex barriers 34. The barriers 34 bound a region 36, in which the Fermi wavelength of the electrons is about 50-100 nm. The mean free path of the electrons is several microns at low temperature. One presentation of the theory of such devices is given in Physical Review B Apr. 15, 1990, 41, pages 7906-7909 “Quantised transmission of a saddle-point constriction”-M. Büittiker. The constriction confines electron states in a direction across the barriers. The wide regions at opposite sides of the constriction provide reservoirs of electrons in local equilibrium. A difference in electrochemical potentials between the reservoirs induces a current through the constriction, and it can be shown the conductance of the constriction in the linear-response regime has the form of a “stair case”, rising with the chemical potential difference, μ, in the reservoirs, as shown in FIG. 3B.

The electron Y-branch switch (YBS) is a device in which electrons injected from the stem of the Y flow selectively into the two branches of the Y under the influence of an electric field. The properties of YBS and similar devices have been studied—see for example Applied Physics Letters 60(2) Jan. 13, 1992, pages 237-239 “Analysis of an electron-wave Y-branch switch”, Palm and Thylen. When made small enough, a YBS can be considered as a three terminal device in which the branches of the Y are used to supply and draw current from the device, and an electrochemical potential is measured at the stem of the Y—see IBM J. Res. Develop. Vol. 32 N^{o} 3, May 1988, p. 317-331, “Symmetry of Electrical Conduction”, M. Büittiker. In the linear response regime, for a symmetric device, the electrochemical potential in the stem is a simple average of the electrochemical potentials applied to the left and right branches and, thus, the measured voltage at the stem will be zero when the applied voltages at the left and right branches are equal and opposite.

DE-A-19757525 discloses a rectifying arrangement comprising a triangular-shaped etching at the junction between collinear current flow paths such as to induce a rectified voltage in a path perpendicular to the current paths.

SCIENCE, Volume 283, Mar. 19, 1999 “An adiabatic quantum electron pump” Switkes et al, reports a quantum pumping mechanism that produces DC current or voltage in response to a cyclic deformation of the confining potential in an open quantum dot.

U.S. Pat. No. 5,369,288 discloses a construction of quantum semiconductor device wherein the output is substantially free of scattering effects. U.S. Pat. No. 5,270,557 discloses a quantum point contact provided with a control electrode over the constriction area of the contact.

EP-A-0626730 discloses a nano fabricated logic device comprising asymmetrically coupled quantum point contacts providing multiple logic levels. EP-A-0461867 discloses a refraction structure positioned between two quantum point structures to provide a switching action.

### SUMMARY OF THE INVENTION

It is an object of the present invention to provide a novel electronic device, of nanometric dimensions.

In a first aspect, the invention provides an electronic device comprising a region providing ballistic electron flow, and at least -first and second conductance paths providing electron flow to or from said region, each path having a conductance which varies as a function of electron energy therein, means for applying an external potential to one or both of the conductance paths, and means for sensing a potential developed in said region.

In accordance with the invention, a potential is developed within said region, which is determined by the states of the first and second conductance paths. In accordance with the invention, there usually exists a non-linear relationship between the applied potential and sensed potential. Thus the device operates in a non-linear regime, and potentials may be applied of the order of volts, and sensed potentials may be of the order of volts. This is to be contrasted with prior art devices operating in a linear regime, where the potentials are, at a maximum, of the order of millivolts.

The sensed potential may be employed to influence the operation of an adjacent device, as will be described below, and to this end the central region may be in the form of a stem providing a probe. It may however be difficult in practice in some circumstances to sense the potential developed within the region.

In accordance with a more specific form of the invention, there is provided an electronic device comprising a region providing ballistic electron flow, and at least first, second and third conductance paths providing electron flow to or from said region, each conductance path having a conductance which varies as a function of electron energy therein, means for applying an external potential to one or more of the conductance paths, and means for sensing a potential, or parameter related thereto, at one or more of the conductance paths.

Under usual operating conditions, there exists a non-linear relationship between applied potential and sensed potential or parameter related thereto. The conductance is a linear response conductance in which the conductance value G=I/V.

Said external potential will usually be a voltage, or electrochemical potential, but other sources of energy potential may be envisaged. Similarly the sensed potential will normally be a voltage, or electro-chemical potential, existing in the conductance path remote from said region.

It is convenient to describe the device of the invention, and to perform measurements, by means of the electrochemical potential, since this can be precisely determined. Electro chemical potential is a potential related to chemical potential by addition of a term −eV, where −e is the charge of an electron, and V is the applied voltage. Chemical potential μ is a well-defined thermodynamic quantity:

μdN=dU+pdV−TdS

where the terms have their usual meaning in thermodynamics.

Potentials are usually applied and sensed in local electron reservoirs, existing at electrical contacts on the outer ends of the conductance paths remote from said region providing ballistic electron flow, where it is simpler, as a matter of practice, to perform such operations. In such reservoirs, there exists a local electro-chemical potential. Alternatively or in addition, external voltages may be applied, to control the conduction of conductance paths, on gates positioned close to but electrically insulated from the conductance paths. Such gates operate by modulating a depletion region within the conductance paths. Application of external voltages alters the energy of electrons injected into the conductance paths and induces current flow through the paths. Thus each conductance path forms a terminal or port for current flow. Voltages and currents can be applied and monitored at such terminals or ports. In some applications, current flow may not necessarily occur through the path, but a voltage developed at the path may be monitored or employed as a probe voltage.

External electrical contact is made to the conductance paths of the device of the invention by contacts, in per se known manner, to permit current flow and application of external voltage. The contact acts as a local reservoir for electrons, and this is the operative reservoir for the purposes of influencing the characteristics of the device.

In a further aspect, the present invention provides an electronic device consisting of a region providing ballistic electron flow, and at least first and second conductance paths for electron flow to or from said region which are such that there exists for each path a reservoir of electrons in at least temporary local equilibrium defining a local electrochemical potential, and means for applying first and second voltages to respective reservoirs, the first and second paths being such that the conductance value for electron flow through each of the first and second paths is dependent upon the applied voltage, whereby to create a non-linear rectifying or transistor action for electron flow through said paths.

In a still further aspect the invention provides an electronic device consisting of a region providing ballistic electron flow, and at least first, second and third conductance paths for electron flow to or from said region which are such that there exists for each path a reservoir of electrons in at least temporary local equilibrium defining a local electrochemical potential, and means for applying first and second voltages to reservoirs associated with said first and second paths, the first, second and third paths being such that the conductance value for electron flow through each path is dependent upon the applied voltage, whereby to create a non-linear rectifying or transistor action between electron flow through said paths.

The conductance paths may have any desired relationship, provided it is not constant (ohmic), between the conductance and the energy of electrons passing through the conductance path. The electron energy will depend in general on temperature and applied voltage, and any other applied external force. In the case where the conductance path is a quantum point contact, then, as described above, the linear-response conductance is in the form of a “staircase” at low temperature, rising with chemical potential in the reservoirs. However, other types of conductance paths may be envisaged, for example quantum wires, silicon nanowire devices having a non-linear relation between current and voltage, resonant tunnelling devices or quantum dots. For resonant tunnelling diodes and quantum dots, the conductance is represented as a series of peaks for increasing voltage or chemical potential in the reservoirs.

Said region may consist of a small area forming a central junction between the conductance paths. Alternatively the region may cover the entire device of the invention, the conductance paths being formed by etching within the region or otherwise, to define electron flow paths to and from the central region. In such a configuration, the entire device may be regarded as a so-called ballistic junction.

As preferred where a conductance path is formed as a quantum point contact, it is defined by a constriction or saddle point in a path for electron flow. The constriction is formed by etching to provide smooth contours of a barrier wall. However other means of defining the constriction may be envisaged—for example, superimposed split gates providing electron depletion on either side of a flow path.

Geometrically, the device may take many forms, the electron flow paths through the conductance paths extending from a central region at any desired angle to form devices having the form for example of a T, Y, ε or arrowhead. One convenient shape described herein is a Y shape with a base (or stem) and branches (or arms); however the invention is not restricted to this particular geometry.

The device according to the invention will usually be formed of three conductance paths; however for some applications more than three paths may be desired.

In one mode of operation, it has been found that if an alternating voltage is applied across two of the conductance paths, then a unipolar voltage is induced at the third conductance path. In other words, the device acts as a rectifier. Essentially, the transmissivity of a flow path is dependent on the energy at which the electrons are injected. Thus if a positive voltage is applied to one of the paths, the injected electron energy will decrease, and therefore the transmissivity of the branch will decrease. If a negative voltage is applied to the other path, the electron energy will increase and the transmissivity of the path will increase. Negative current flow into the third flow path will be determined by current flow from the path with the higher transmissivity, whereas flow out will be determined by the path with the lower transmissivity. Thus there is a net build up of electrons, and therefore a negative voltage output, in the third path when the voltages are applied to the symmetric two paths in a push-pull fashion.

In another mode of operation of the invention, it has been found that where a voltage is applied across two of the conductance paths such that electrons flow from one conductance path to the other, the electron flow will be influenced by a voltage applied to the contact of the third conductance path. The voltage at the contact of the third conductance path may be applied from an external source; alternatively the voltage may be induced from the voltages and electron flow between the other two paths. Further, it has been found that the voltage induced at the third path has a non-linear relation to the voltage across the other two conductance paths. Thus for a given voltage at the contact of one conductance path, and with a voltage applied at the contact of another path causing electron flow, a voltage at the third conductance path is induced and there exist a non-linear relation between the voltage applied to the contact of the second path and the voltage induced at the third path. This non-linear relationship is essentially in two stages, firstly an initial linear relationship, followed by a saturation region. Such a characteristic is similar to a transistor characteristic. In this “transistor” mode of operation, the contact of one, say the first, conductance path is held at a constant voltage, which implies a certain electrochemical potential and Fermi level. Thus, when a voltage is applied to the contact of another, say the second, conductance path, a voltage is induced at the third conductance path, and this induced voltage will be influenced by the voltage at the contact of the first conductance path. Initially, the first conductance path has little effect on the voltage induced at the third conductance path, for low voltages at the second conductance path. This will result in an approximately linear increase of the voltage at the third conductance path as the voltage at the contact of the second conductance path rises. However, when the voltage at the contact of second conductance path reaches such a level that the associated Fermi level approaches and becomes further lower than that in the contact of the first conductance path, then the first conductance path becomes a net supplier of electrons to the current flow, and the voltage at the third conductance path tends to remain constant for rising voltage at the contact of the second conductance path.

In another preferred form of the invention, a 2DEG region provides a current flow path between first and second conductance paths. A conductive region extends from the flow path between the two conductance paths to define a stem or spur, in which a potential is induced. This stem or spur may be used as a control probe or electrode to control another device, for example it may project towards the path of electron flow in an electron waveguide, in order to control current flow therein, and thereby achieve amplification.

The device of the invention may be employed to generate second or higher order harmonic oscillations from an applied frequency, or double or higher order multiplication of frequencies.

The device of the invention may be employed to achieve logical AND or OR functions.

It is recognized that transistors of the bipolar type and FET type, have reached a point of miniaturisation where they cannot easily be made smaller. New types of devices are therefore required. U.S. Pat. No. 5,367,274 and U.S. Pat. No. 6,091,267 are examples of this. However, further improvements are desirable.

In a further aspect, the invention provides an electronic logic device comprising first, second and third terminals, each terminal including an electrical contact connected by a respective conductance path providing electron flow to a central region of ballistic electron flow, the arrangement being such that input signal potentials applied to first and second terminals provide an output signal potential at the third terminal according to a pre-determined logic function.

In a still further aspect, the invention provides an electronic logic device comprising first, second and third terminals, each terminal including an electrical contact connected by a respective conductance path providing electron flow to a central region of ballistic electron flow, the arrangement being such that input signal potentials applied to first and second terminals provide an output signal potential at the third terminal according to an AND or OR logic function.

### BRIEF DESCRIPTION OF THE DRAWINGS

Preferred embodiments of the invention will now be described with reference to the accompanying drawings, wherein:

FIGS. 1A and 1B schematic views of the construction and energy characteristics of a known heterostructure providing a 2DEG;

FIGS. 2A and 2B are a sectional constructional view and an energy diagram of a known quantum well structure for providing a 2DEG;

FIG. 3A is a schematic view of a known quantum point contact formed by a smooth constriction, for use in explaining the present invention and FIG. 3B is a graph of the linear-response conductance of the point contact with a saddle-point confinement versus the chemical potential μ at low temperature;

FIG. 4 is a schematic view of a first embodiment of the present invention;

FIG. 5 comprises transmission traces associated with electrons passing the conductance paths of the embodiment of FIG. 4, plotted against the voltage applied to the side gates;

FIG. 6 is a graph showing measured voltage at the third conductance path of FIG. 4 as a function of the voltage applied to the left conductance path, with the voltage at the right conductance path being varied in a push-pull fashion;

FIG. 7 is a graph of the voltage output from the third conductance path versus the voltage applied to the left conductance path, these values being calculated values to show the correspondence between experiment and theory;

FIG. 8 is a graph of the characteristics of the device of FIG. 4 configured to operate as a diode;

FIGS. 9 and 10 are graphs, for the first embodiment of FIG. 4, of the calculated voltage relationship between the first and third conductance paths, with various voltages applied to the second conductance path;

FIG. 11 is a plan view of a second embodiment of the present invention comprising a scanning electron micrograph of the centre section of the device;

FIG. 12 is a conceptual diagram of the device according to the invention;

FIGS. 13A and 13B are conceptual views of the device according to the invention illustrating its use as a logic gate;

FIG. 14 is a graph showing output voltage for an input sweep voltage, illustrating use of the device as a frequency-doubling device;

FIG. 15 is a circuit diagram of the device according to the invention incorporated in a circuit for providing an AND function;

FIG. 16 is a schematic diagram of a logic circuit including two devices according to the invention interconnected in order to provide an AND function;

FIG. 17 is a schematic diagram of a logic circuit including two devices according to the invention interconnected to provide a NAND function; and

FIG. 18 is a schematic circuit diagram of a device according to the invention providing an inverter function.

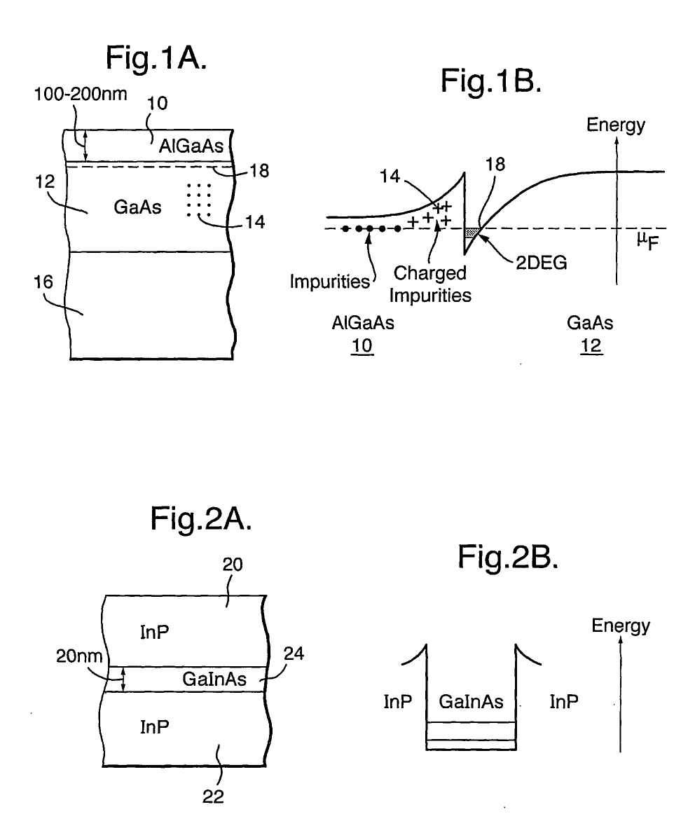

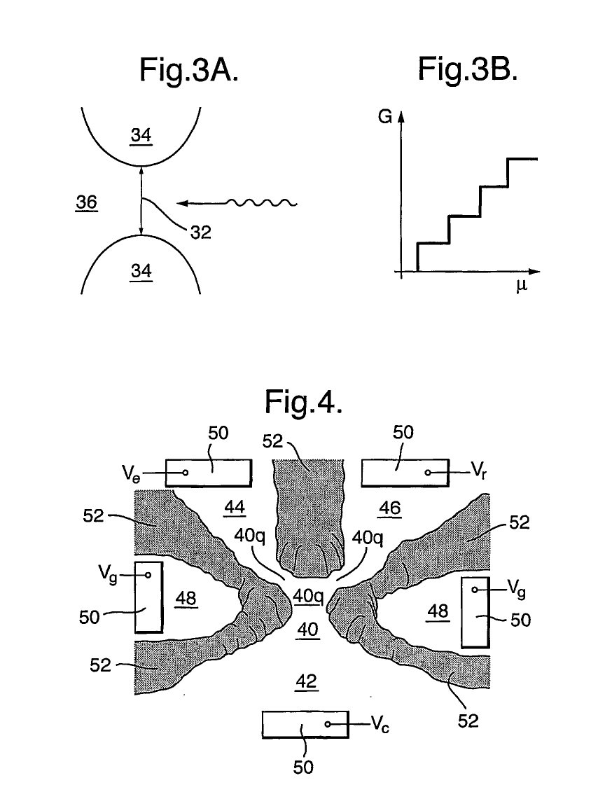

### DESCRIPTION OF THE PREFERRED EMBODIMENT

In a preferred embodiment of the invention, an electronic device operates in a non-linear response regime. The device is made from high mobility GaAs/AlGaAs heterostructures. Three interconnected conductance paths are formed in a region of high mobility, providing a 2DEG. The device defines a geometric Y form having left and right branches and a stem. When finite voltages Vₗ and Vᵣ, are applied to the left and right branches in a push-pull fashion (Vₗ=−Vᵣ), while keeping the centre stem conductance path floating, the measured voltage V_{c} of the stem conductance path will always be negative. This result is unexpected for the known symmetric YBS made from classical conductors, for which Ohm's law implies a zero output, V_{c}=0, from the stem.

It will be understood that to each conductance path there is connected a reservoir of electrons in local equilibrium. Each reservoir has a respective local Fermi level and respective electrochemical potential. Where an ohmic contact is made to the conductance path, the electrochemical potential will be defined as that existing at the ohmic contact.

FIG. 4 is a schematic perspective view of a region 40 of an electron device fabricated by electron beam lithography and wet chemical etching from a modulation doped GaAs/AlGaAs heterostructure. The device has a two-dimensional electron gas located 80 nm below the surface. On the unprocessed wafer, the carrier density and the mobility determined at 4.2 K are about 3.7×10¹¹ cm⁻² and 2×10⁶ cm²/Vs, respectively. The region 40 has ballistic transport properties for electron flow, with a mean free path much greater than the width of the region. Electron beam lithography and wet chemical etching was performed to fabricate 180 nm wide and 100 nm deep trenches 52. Conductance paths 42, 44, 46 are thereby formed in region 40. Each path is contoured to provide a quantum point contact 40q, having a lithographically defined width of 180 nm and a length of 100 nm. Side gates 48 are provided extending adjacent to paths 44, 46, to which gate voltages are applied. Trenches 52 isolate the 2DEG in the side gates 48 from the electrons in the paths 42, 44, 46.

The left and right paths 44, 46 are biased in a push-pull fashion by voltages Vₗ, Vᵣ while the side gates 48 are used to control the depletion in the paths 44, 46 by application of voltage V_{g}. Ohmic contacts 50 connect voltages Vₗ, Vᵣ, V_{c}, V_{g} to the respective paths and gates.

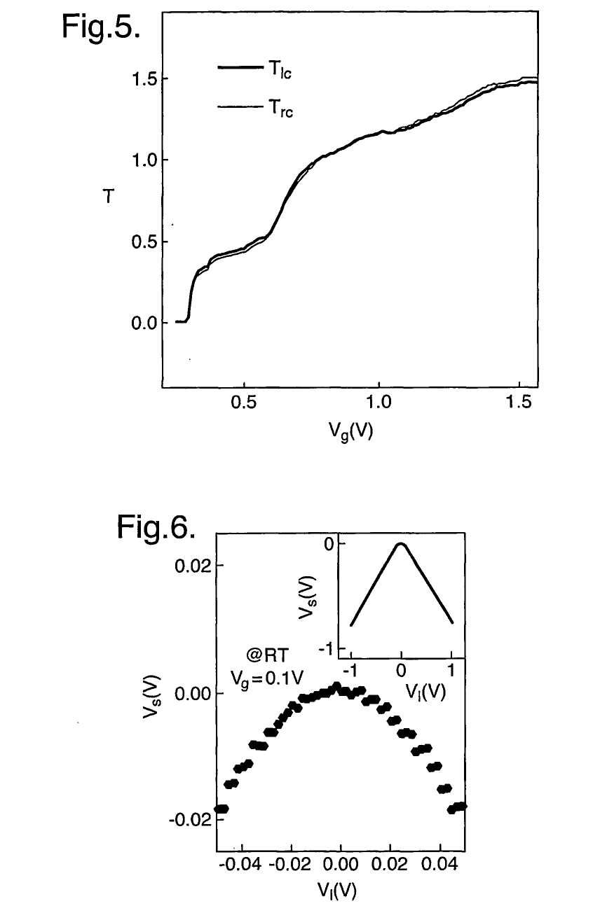

FIG. 5 shows the transmission traces of the device, measured using standard lock-in techniques, between the stem and the left reservoir (T_{lc}) associated with conductance paths 42 and 44 and between the stem and the right reservoir (T_{rc}) associated with conductance paths 42 and 46, versus voltage V_{g} applied to the side gates 48. The contacts 50 to the side gates are ohmic. Thus the voltage at the side gates is sensed by a voltmeter in the voltage source connected to the side gates. It can be seen that the device does not show conduction between the stem reservoir and the two branch reservoirs until the voltage applied to the side gates is higher than a positive threshold of Vₜₕ=0.28 V. This is due to the fact that the etching process introduces surface states on the sidewalls, leading to strong depletion around the structure. Conductance quantization is clearly seen in the measured transmissions T_{rc} and T_{lc}. FIG. 5 also shows that the two transmission traces, T_{lc} and T_{rc} can hardly be distinguished, which indicates that the device is almost perfectly symmetric with respect to the stem. The fact that the first plateaus in the transmissions T_{lc} and T_{rc} appear at a value of ½ is not due to the lift of spin degeneracy. This plateau is a consequence of a perfect adiabatic, ballistic process of the electron transport from the stem to the two branches. For a symmetric, ballistic device with adiabatic boundaries, the transmissions between the stem reservoir and the two branch reservoirs are determined solely by the conductance of the stem, G_{c}, via the relation of T_{rc}=T_{lc}=(h/4e²)G_{c}, the two branches being wide enough to receive electrons injected from the stem reservoir.

As shown in FIG. 4, voltage connections are made to the left and right branch reservoirs creating with differences in the electrochemical potential, while the voltage output from the floating stem reservoir is measured via an ohmic contact. The results are shown in FIG. 6, where the measured voltage of the centre stem reservoir Vₛ has been plotted versus the voltage applied to the left reservoir Vₗ of the device. The voltage of the right electron reservoir is Vᵣ=−Vₗ, i.e., the voltages are applied to the left and right branch in a push-pull fashion. The measured curves are symmetric with respect to Vₗ=0. The gate voltage is 0.1 V. Measurements are made at room temperature. The large scale curve shows a quadratic dependence on Vₗ for small values of |Vₗ| and to have negative values at both positive Vₗ and negative Vₗ. For large values of voltage, measured in volts, the small scale curve clearly shows a rectifying relationship between Vₗ and Vₛ. These measurements show clearly that when finite voltages are applied to a symmetric, ballistic device in a push-pull fashion, the output stem voltage Vₛ will always be negative. This effect is observable not only in the low voltage region, but also in the region where high voltages are applied. This novel property does not appear in the linear-response regime of electron transport, and that it is not observable if the device is constructed from classical, diffusive conductors, for which Ohm's law implies a zero output, Vₛ=0, from the stem.

To study the physical origin of the novel effect, we have carried out model calculations for the device as shown in FIG. 4, based on the concept of a non-linear response for a three-terminal ballistic junction (TBJ). In the calculations, three conductance paths were each described by a saddle-point potential of the form V(x, y)=V₀−½m*ω²x²+½m*ω²y² where V₀ is the electrostatic potential at the saddle, m* is the electron effective mass, x and y define the co-ordinate along and perpendicular to the transport direction, respectively. Since the measured devices were made by etching, resulting in strong confinement in the conductance paths, the application of a voltage on the side gates does not change the shape of the confinement potential, but rather the potential V₀ at the saddle. The parameters [symbol] ωₓ=6 meV and [symbol] ω_{y}=15 meV were used for the three conductance paths and were independent of the side gate voltage. However, several values of V₀ were used in order to simulate a situation where different voltages were applied to the side gates. The Fermi energy was taken to be μ_{F}=14 meV, corresponding to an electron density of 3.9×10¹¹cm⁻² in the 2DEG region. When voltages Vₗ and Vᵣ are applied to the left and right branch reservoirs, the electrochemical potentials in the two reservoirs shift to

μₗ=−eVₗ+μ_{F} and μᵣ=−eVᵣ+μ_{F}

respectively. The electrochemical potential in the floating centre stem reservoir μ_{c} is determined by the condition that the current at the stem reservoir I_{c}=0, while the output voltage from the stem reservoir is given by V_{c}=−(μ_{c}−μ_{F})/e. For a symmetric, ballistic device, the electron transmissions T_{lc} and T_{rc} depend only on the conductance of the stem. Thus, the functional characteristics of V_{c} versus Vₗ are determined mainly by the behaviour of the conductance of the stem whereas the detailed layout of the YBS structure is not important.

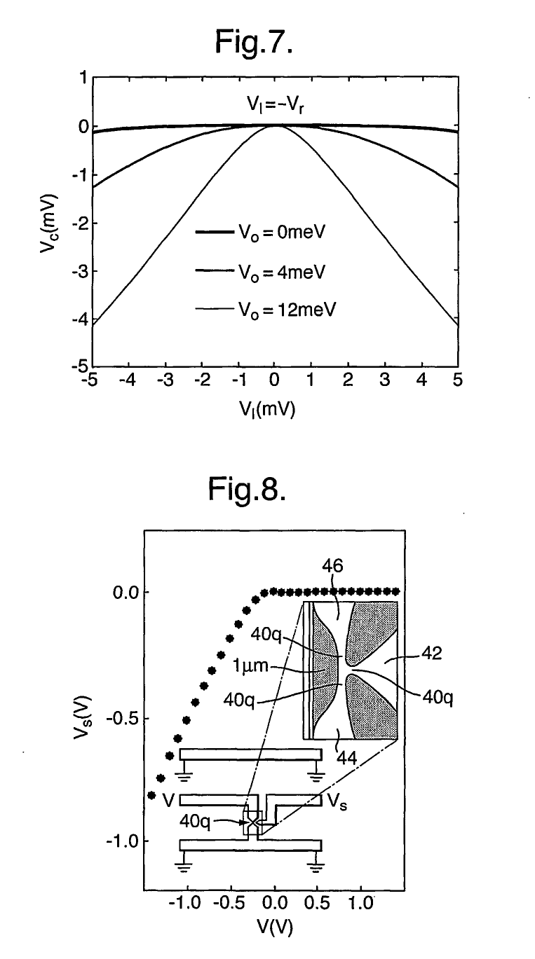

FIG. 7 shows the results of the calculations for the present device operated in a push-pull fashion, Vₗ=−Vᵣ. The calculated V_{c} have been plotted versus Vₗ for three values of the potential at the saddle V₀. For V₀=0 meV, the transmissions T_{lc} and T_{rc} at the energy of μ_{F}=14 meV, are on a plateau. This is the situation corresponding to a voltage of 1.0 V being applied to the side gates. Thus, the current flow between the left branch and the stem reservoir depends, approximately, linearly on the difference in the electrochemical potential between the two reservoirs. The same holds also for the current flow between the right branch and the stem reservoir. The system behaves, therefore, like a three-terminal device built from linear conductors, where Ohm's law is applicable. As a result, for the device operated in push-pull fashion the output voltage V_{c} should approximately stay at zero at small values of |Vₗ| as shown in the top curve of FIG. 7. For the case of V₀=4 meV, corresponding to the experimental situation of V_{g}=0.6 V, the transmissions T_{lc} and T_{rc} at the energy of μ_{F}=14 meV, are between values described by plateaux. The negative current flow into the stem reservoir which occurs for an increase, e|Vₗ|, in the electrochemical potential in the either of the two branch reservoirs with respect to the potential of the stem reservoir, is always larger than the negative current flow out of the stem reservoir, for the same small amount of the decrease in the electrochemical potential in the other branch reservoir. To establish the current balance in the floating stem (I_{c}=0), the electrochemical potential ∥_{c} has to increase to a value between μ_{F} and μ_{F}+e|Vₗ|. Thus, the measured output voltage from the stem reservoir is seen to be always negative, as was shown in the middle curve of FIG. 7. In addition, the calculated V_{c} shows a good quadratic dependence on Vₗ for small |Vₗ|. For the case of V₀=12 meV, the transmissions T_{lc} and T_{rc} at the energy of μ_{F}=14 meV are close to pinch off, as in the experiment at V_{g}=0.3 V (see FIG. 5). The output stem voltage V_{c} remains negative for all finite values of Vₗ, which is the same as in the calculation for V₀=4 meV. However, compared with that calculation, relatively larger negative output voltage V_{c} at a given finite Vₗ is found, in agreement with the experiment. All these features can be understood similarly as for the calculation for the case of V₀=4 meV.

Experimental observations are well explained by the model based on three ballistically coupled quantum point contacts. The good agreement between theory and experiment shows that the experimentally observed novel effect is an intrinsic property of three-terminal ballistic junctions (TBJs) in a non-linear response regime. The calculations also indicate that the novel effect will be observable as long as the conductance of the three conductors, of which a three-terminal junction is composed, increases with the electrochemical potential provided the size of the device is smaller than the mean free path of the electrons. This novel effect is observed at room temperature, since it is possible to make such devices with dimensions of the order of 100 nm or below, comparable to the mean free path of high mobility materials at room temperature.

The present invention provides a novel property in a GaAs/AlGaAs ballistic Y-branched device. When two voltages are applied to the left and right branch reservoirs, the electrochemical potential of the floating stem reservoir tends to take the higher value of the electrochemical potentials in the two branch reservoirs. Thus, for a symmetric device with voltages being applied in the push-pull fashion to the two branch reservoirs, the output voltage from the stem reservoir will always be negative. The novel effect is confirmed by calculations based on a non-linear response theory of electron transport. The existence of ballistic transport in the device is found to be the precondition of the observed effect. It is predicted that the novel phenomena observed is universal for nanometer-scaled devices. Implications of feature-downscaled Si technology suggests a basis for extremely compact devices and circuits based on this type of behaviour.

Referring to FIG. 8, this shows in the inset a device similar to that of FIG. 4, with conductance paths 42, 44, 46 providing quantum point contacts 40q. A schematic view of the device is shown in the main part of FIG. 8. The device is connected to act as a rectifier with a voltage V applied to the left branch, a voltage Vₛ measured at the central stem branch and with the right branch grounded. The measurements are made at room temperature and the voltages are measured in volts. A diode characteristic can be seen, with the output voltage Vₛ remaining at 0V, until the input voltage V goes lower than a threshold, just below 0V, at which point the output voltage rapidly decreases.

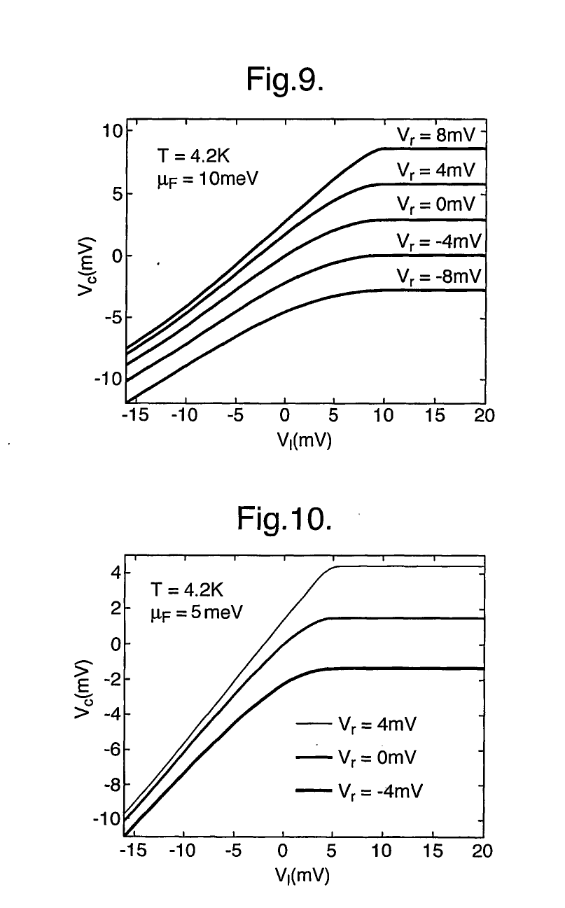

It is possible to operate the first embodiment in a transistor-like mode, as indicated by the graphs in FIGS. 9, and 10. FIG. 9 is graph for an absolute temperature of 4.2° Kelvin with the region 40 having a Fermi level of 10 meV. FIG. 10 is a similar graph for an operating temperature of 4.2° Kelvin with a Fermi level of 5 meV. In this mode of operation, the voltage at the right conductance path 46 is held constant at a given value and the voltage relation between the contacts that connect conductance paths 42, 44 are shown. It may be seen for any given value of Vᵣ, the relationship between Vₗ and V_{c} is non-linear, having an approximately linear relation for negative values of Vₗ and V_{c}, and a saturated region for positive values of Vₗ in which V_{c} remains constant. It may be seen that as the voltage Vᵣ is changed, the relationship between Vₗ and V_{c} remains essentially the same but the precise values change so that the saturation voltage of V_{c} is much higher at positive value of Vᵣ than for negative values of Vᵣ. It may be seen that this produces essentially a family of transistor-like curves, and shows that the device may operate as a transistor with a modulating voltage Vᵣ being applied to conductance path 46.

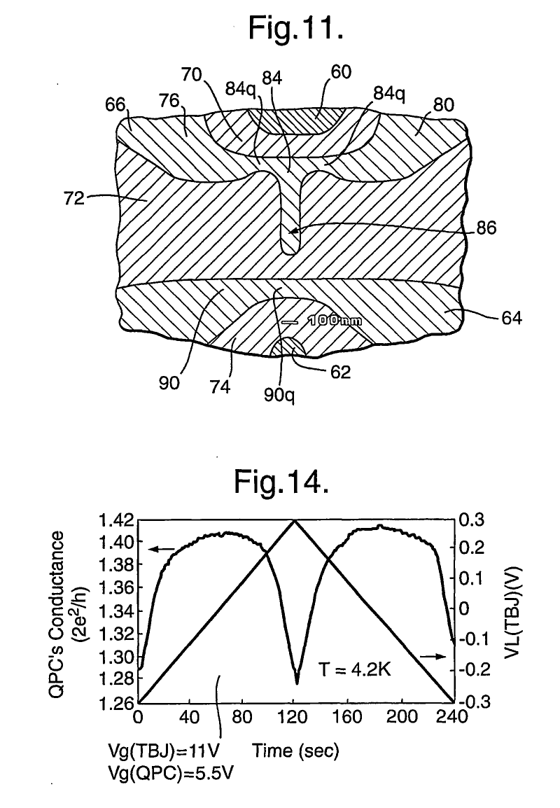

Referring now to FIG. 11, there is shown a second embodiment of the invention configured as a transistor. The device comprises conductive regions 60, 62, 64 and 66 separated by etched isolating regions 70, 72, 74. These etched isolated regions may be filled with an insulating material. Conductive region 66 is, in this example, generally T-shaped with a left arm 76 and a right arm 80. Between arms 76 and 80 is a region 84 providing ballistic transport of electrons, with a mean free path far greater than the width of region 84. Arms 76 and 80 in the region of region 84 are contoured to provide quantum point contacts 84q. A spur or branch 86 extends from region 84 to form a voltage probe. Conductive region 64 narrows at its central area to define a conductance path 90 and defining a quantum point contact 90q. Conductive regions 60, 62 provide gates for applying control voltages.

In operation, electron flow through conductance paths 76, 80 and zone 84, induces a voltage in spur 86. This voltage modulates, by depletion, the flow of electrons in conductive regions 64 through conductance path 90. Thus a transistor-like action is provided, giving a function of amplification of electron flow in constrictions 76, 80 in the electron flow through constriction 90.

The device of FIG. 11 may be used for frequency multiplication of input frequencies applied to the left and right conductance paths, and the sum of the frequencies, together with harmonics, thereof, is obtained in path 90. This is shown in FIG. 14, wherein a saw-tooth ramp voltage is applied to the left and right branches over a long sweep time period of 240 seconds. A rectified voltage wave appears at the central branch, giving a waveform at double frequency. Higher harmonics are also generated.

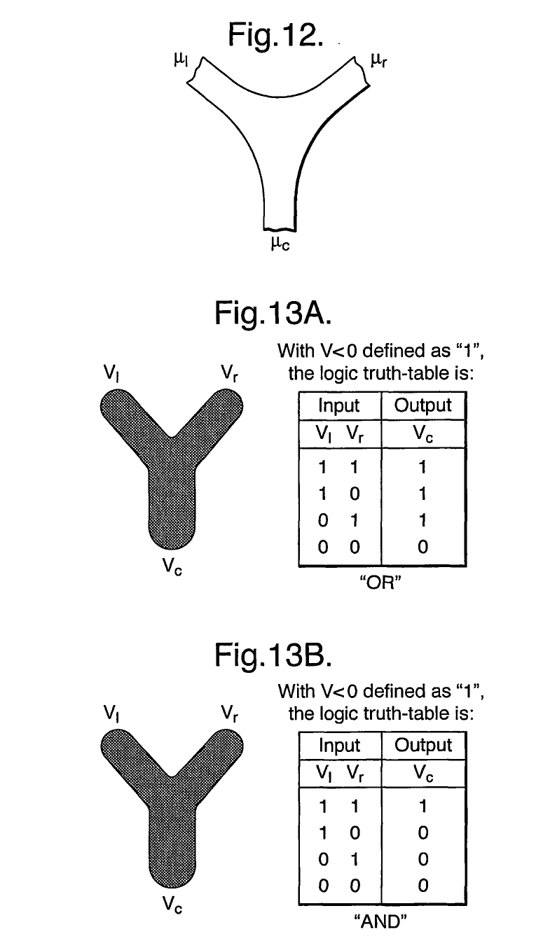

Although the present invention must be regarded as a novel concept, it is possible to understand the concept more clearly with reference to a mathematical analysis. Consider a three-terminal ballistic junction (TBJ), i.e. a system as shown in FIG. 12. In order to reveal the fundamental physics, but avoid lengthy, detailed calculations, the invention is modelled by connecting three (left, right and central) quantum point contacts (QPCs) as conductance paths having outer electrochemical potentials μₗ, μᵣ, μ_{c} in their outer reservoirs, via a region with sufficiently smooth (i.e., adiabatic) boundaries. If the symmetric case, in which the left and right branches are made identical, is considered, the question asked is: When a bias 2|V| is applied between the left and right reservoirs, giving |μₗ−μᵣ|=2e|V|, what is the output voltage V_{c}, at the floating central reservoir μ_{c}? To answer this question, we need to know various transmission probabilities, Tᵢⱼ, between the three probe reservoirs (i, j=l, r, or c) of the device and the reflection probabilities, Rᵢᵢ, and to calculate the current in the central contact from

$$\begin{matrix}{I}_{c} = \frac{2 e}{h} \{ \int [ {N}_{c} ( E ) - {R}_{cc} ( E ) ] f ( E - {μ}_{c} , T ) ⅆ E - \\ {\sum }_{i = l , r} \int {T}_{c i} ( E ) f ( E - {μ}_{i} , T ) ⅆ E \}\end{matrix} \qquad ( 1 )$$

where N_{c} is the number of quantum channels (occupied subbands) in the lead from the central reservoir to the central QPC, μₗ=μ_{F}+eV and μᵣ=μ_{F}−eV the electrochemical potentials in the left and right reservoir (μ_{F} is the electrochemical potential in the TBJ at the zero bias), T the temperature at the reservoirs, and ƒ(E−μ_{c},T) the Fermi-Dirac function.

The output voltage from the central branch, V, can be calculated from eV_{c}=−(μ_{c}μ_{F}), where the electrochemical potential μ_{c}, need to determined from Eq. (1) by requiring I_{c}=0.

Various symmetric properties of the transmission probabilities can be obtained; time-reversal invariance in the absence of a magnetic field implies T_{cl}=T_{lc}, T_{cr}=T_{rc}, and Tₗᵣ=Tᵣₗ, while current conservation gives

N_{c}(E)−R_{cc}(E)=T_{lc}(E)+T_{rc}(E),

Nₗ(E)−Rₗₗ(E)=T_{cl}(E)+Tᵣₗ(E),

Nᵣ(E)−Rᵣᵣ(E)=T_{cr}(E)+Tₗᵣ(E). (2)

The probability for transmitted electrons through a QPC to be scattered back is very small, provided that there are an enough number of open channels in other two QPCs to receive the electrons. In this adiabatic situation, the left-hand side in each of the above equations is simply proportional to the linear-response conductance of the corresponding QPC, for instance, G_{c}(E)=(2e²/h)[N_{c}(E)−R_{cc}(E)]. Thus, Eq. (2) can be rewritten to express the transmission probabilities in terms of the linear-conductance of the three QPCs,

$$\begin{matrix}{T}_{cl} ( E ) = {T}_{l c} ( E ) = \frac{h}{4 {e}^{2}} [ {G}_{c} ( E ) + {G}_{l} ( E ) - {G}_{r} ( E ) ] , \\ {T}_{cr} ( E ) = {T}_{rc} ( E ) = \frac{h}{4 {e}^{2}} [ {G}_{c} ( E ) + {G}_{r} ( E ) - {G}_{l} ( E ) ] , \\ {T}_{lr} ( E ) = {T}_{rl} ( E ) = \frac{h}{4 {e}^{2}} [ {G}_{l} ( E ) + {G}_{r} ( E ) - {G}_{c} ( E ) ] .\end{matrix}$$

These simple relations are valid only for a device with adiabatic geometrical boundaries and in the condition that the conductances of the three point contacts are in the combinations such that the right-hand sides of the three equations in Eq. (3) are larger than or equal to zero.

Although Eq. (3) has been derived for a general adiabatic device, it can be greatly simplified for the case where the device is symmetric, i.e., when the left and right branch of the device are made identical. In this case, we have Gₗ=Gᵣ. Inserting this into Eq. (3), we immediately obtain that T_{cl}(E)=T_{cr}(E)=(h/4e²)G_{c}(E) and Tₗᵣ(E)=Tᵣₗ(E)=(h/4e²)[2Gₗ(E)−G_{c}(E)] for Gₗ(E)≧(½)G_{c}(E).

Thus, for a symmetric, adiabatic TBJ, the condition that determines the electrochemical potential in the central reservoir μ_{c}, can be written as

$$\begin{matrix}\int {G}_{c} ( E ) f ( E - {μ}_{c} , T ) ⅆ E = \frac{1}{2} \int {G}_{c} ( E ) f ( E - {μ}_{l} , T ) ⅆ E + \\ \frac{1}{2} \int {G}_{c} ( E ) f ( E - {μ}_{r} , T ) ⅆ E\end{matrix} \qquad ( 4 )$$

It is important to notice that when a bias is applied to the left and right branch of a symmetric TBJ, the electrochemical potential and thus the output voltage in the floating central probe is solely determined by the conductance, G_{c}(E), of the central QPC, and is independent of the structure of the left and right branch as well as the angle between the two branches, as long as Gₗ(E)+Gᵣ(E)≧G_{c}(E) is satisfied. It should also be emphasized that Eq. (4) implies that if the TBJ was made from linear conductors for which G_{c} is independent of the energy E of injection electrons, the output voltage in the central probe would always stay at zero when voltages V and −V were applied to the left and right branch.

Another very important result which can be derived from Eq. (4) by making Taylor expansions in terms of V in the two sides of the equation (using the relations:

μ_{c}−μ_{F}=−eV_{c};

μₗ−μ_{F}=−eVₗ; and

μᵣ−μ_{F}=−eVᵣ)

for a symmetric, adiabatic device is that at a small value of |V|, the output voltage V_{c} can be written as

$$\begin{matrix}{V}_{c} = - \frac{1}{2} α {V}^{2} + O ( {V}^{4} ) \\ where & ( 5 ) \\ α = - e \frac{\int {G}_{c} ( E ) \frac{{\partial }^{2} f ( E - {μ}_{F} , T )}{\partial {E}^{2}} ⅆ E}{\int {G}_{c} ( E ) \frac{\partial f ( E - {μ}_{F} , T )}{\partial E} ⅆ E} & ( 6 )\end{matrix}$$

Thus, V_{c} depends quadratically on V for small |V|. Furthermore, for ∂G_{c}(μ)/∂μ>0, one gets α>0. Thus, one always has V_{c}<0 when V and −V are applied to the left and right branch of the symmetric device. This means that the electrochemical potential in the central probe, μ_{c}, always moves upwards and tends to take the higher value of the fit and μᵣ. It can be shown by carrying out detailed calculations that this characteristic response of μ_{c} is valid not only in the limit of small |V|, but can also be valid for large values of |V|.

It is interesting to consider the calculations at the zero temperature for which a simple equation for determining the electrochemical potential in the central probe, μ_{c}, can be derived,

$${\int }_{{μ}_{c}}^{{μ}_{l}} {T}_{c l} ( E ) ⅆ E = {\int }_{{μ}_{r}}^{{μ}_{c}} {T}_{c r} ( E ) ⅆ E \qquad ( 7 )$$

This is because the Fermi-Dirac function no longer appears, and the three integrals can simply be made over E from (minus infinity) to their corresponding electrochemical potentials. Splitting the left side (4) into two halves, and rearranging, (7) is obtained. It is clear that this equation satisfies the requirement of current conservation. For a symmetric TBJ with adiabatic boundaries, one has T_{cl}(E)=T_{cr}(E)=(h/4e²)G_{c}(E) [see Eq. (3)]. For the central QPC with ∂G_{c}(μ)/∂μ>0 in the electrochemical potential window between μₗ and μᵣ, Eq. (7) implies that the electrochemical potential in the central probe, μ_{c}, will always stay at a value above the average of μₗ and μᵣ,. This again means that when V and −V are applied to the left and right branches of the TBJ, the output voltage V_{c} from the floating central probe is always negative. The quadratic dependence of V_{c} on V in the limit of small values of |V| can also be derived for the zero temperature case. The result is

$${V}_{c} = - \frac{e {G}_{c}^{′} ( {μ}_{F} )}{2 {G}_{c} ( {μ}_{F} )} {V}^{2} + O ( {V}^{4} ) \qquad ( 8 )$$

It is seen that at T=0, the absolute value of the curvature depends solely on the properties of the conductance of the central QPC: It is proportional to the first order derivative of the conductance, G′_{c}(μ_{F}), with respect to the Fermi energy, but it is also proportional to the inverse of the conductance itself, G_{c}(μ_{F}).

The three QPCs are modelled by three saddle-point contacts. The electrostatic potential of each QPC is then in the form of

$$V ( x , y ) = {V}_{o} - \frac{1}{2} {m}^{*} {w}_{x}^{2} {x}^{2} + \frac{1}{2} {m}^{*} {w}_{y}^{2} {y}^{2} \qquad ( 9 )$$

where V₀ is the electrostatic potential at the saddle, m* is the electron effective mass, x defines the coordinate along the transport direction, while y along the transverse direction [19]. The curvatures of the potential are expressed in terms of the frequencies Wₓ and W_{y} which depend, in general, on the effective mass m*. The Hamiltonian of the saddle-point contact, which is given by Eq. (9) supplemented by the kinetic operator −h²∇²/2m*, is separable into a transverse wave function associated with energies

$${ω}_{y} ( n + \frac{1}{2} ) , n = 1 ,$$

2, . . . , and a wave function along x in an effective potential

$${V}_{o} + {ω}_{y} ( n + \frac{1}{2} ) - \frac{1}{2} {m}^{*} {ω}_{x}^{2} {x}^{2} .$$

The transmission probability for this saddle-point potential has a simple form,

$${T}_{m n} ( E ) = {δ}_{m n} \frac{1}{1 + {ⅇ}^{π {ϵ}_{n}}} , \qquad ( 10 )$$

where m and n are the indices for transverse modes, the variable

$${ϵ}_{n} = 2 [ E - {ℏ}_{{ω}_{y}} ( n + \frac{1}{2} ) - {V}_{o} ] / {ℏω}_{x} ,$$

and E is the electron energy. The conductance of the saddle-point contact is given by

$$G ( E ) = \frac{2 {ⅇ}^{2}}{h} T ( E ) = \frac{2 {ⅇ}^{2}}{h} {\sum }_{m , n} {T}_{mn} ( E ) .$$

The above analysis has been carried out for the case where the device is symmetric. However, the invention is not limited to symmetric devices and the novel characteristics of the invention appear even when the device symmetry is broken, provided that the magnitude of the equal and opposite applied voltages at the left and right branches, |V|, is greater than a certain threshold.

Referring now to FIGS. 13A and 13B, there is shown use of the device according to the invention, with voltages applied to the conductance paths according to the tables as shown, in order to generate AND or OR functions. When voltages are applied to the left and right branches of a symmetric TBJ, the output central branch voltage will be positive (a binary value of 1) only when both the applied voltages are positive. Thus the device operates as a logic AND gate. With a negative value of voltage defined as “1”, then the device functions as an OR gate.

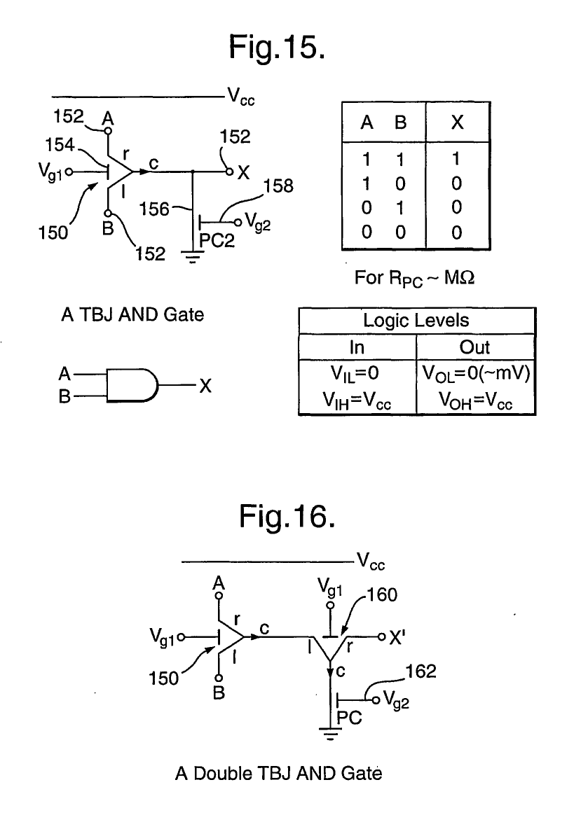

Referring now to FIG. 15, there is shown a device 150 similar to that shown in FIGS. 13 and 4 and wherein three terminals A, B, X include respectively the left, right and central paths (l, r, c)and electrical contacts 152. A sidegate 154 is provided which influences the depletion in the left and right paths equally. A further conductive path 156 is provided interconnecting the central path c of the device to ground reference potential. Path 156 has an ohmic conductance value, but a gate 158 is provided which influences the depletion region in path 156 to alter the resistive value of path 156.

In operation, voltages, selectively applied to terminals A and B, have a ground reference value (0) or the voltage of a supply rail V_{cc}. The voltage of the supply rail is positive and therefore provides an AND function according to the table shown. The two gates 154, 158, permit adjustment of the input voltage levels and output voltage level. As can be seen from the second table in FIG. 15, there is very little internal voltage loss in the AND gate device since the output voltages are essentially applied at the input.

It will be noted in this logic device, that the device is essentially a three terminal device, and that further gates are not necessary for the device to operate. The gates shown are merely for adjusting optimum operating conditions. Further the device does not require application of external power, other than that through the input terminals.

Where device 150 is constructed with the left, right and central arms of similar dimensions, the device is perfectly symmetric in that the AND function may be provided by providing input signals to any two of the three terminals and taking the output signal from the third terminal.

Referring to FIG. 16, this shows a logic circuit wherein similar parts to those shown in FIG. 15 are denoted by the same reference numeral. The circuit performs a AND gate function. A second three terminal device (as shown in FIG. 13) 160 is coupled to the first device, with arm c of device 150 integral with left conductance arm l of device 160. The central arm c of device 160 is connected to ground reference, and a gate 162 influences the depletion region within arm c. The output terminal X′ includes arm r. The second device 160 does not alter the logic function provided by device 150. The function of second device 160 is to adjust the parameters of the output signal.

Referring now to FIG. 17 a logic circuit implementing a NAND function is shown. Two logic devices 170, 172 each of the type shown in FIGS. 4 and 13 are provided, having left, right and central arms (l, r and c) and electrical contacts 174. The central arm c of device 170 is coupled to a gate 176 which influences the depletion in arm l of device 172. Device 170 has input terminals A and B which are connected to receive input signals. The arms l, r of device 172 are connected to ground reference potential and a voltage rail V_{cc} respectively. An output signal is taken from central arm c of device 172 at terminal X. The precise value of the output signal at terminal X is controlled by a gate 178 connected to a conductive path 179 between central arm c and ground reference potential.

The circuit shown performs the NAND function shown in the table. Essentially, the second device 172 provides an inversion of the output signal of the first device 170.

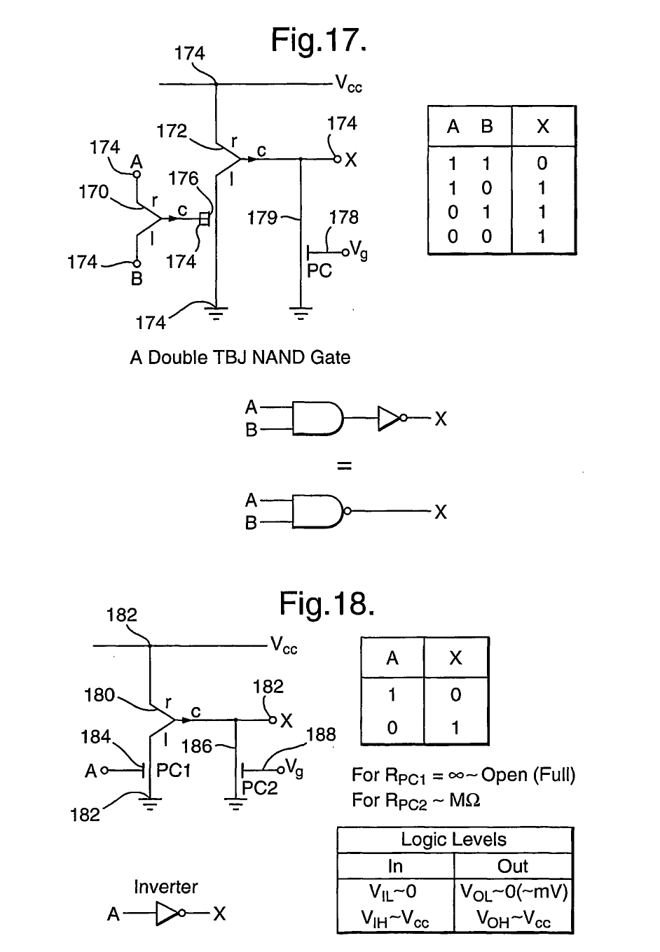

Referring to FIG. 18, there is shown a logic circuit providing an inverter function wherein a device 180, of the type shown in FIGS. 4 and 13, has left, right and central arms l, r, c and electrical contacts 182. The left arm l is connected to ground reference, the right arm r is connected to a voltage V_{cc}, and the central arm c forms an output terminal X. The left arm l has a gate 184 for controlling the depletion region within arm l. Gate 184 is coupled to receive an input signal at terminal A. A conductive path 186 between central arm c and ground reference has a gate 188 for controlling the depletion therein for adjusting the magnitude of the output signal at terminal X. As shown in the table, this arrangement provides an inverter function.

1. An electronic device comprising a region providing ballistic electron flow, and at least first and second conductance paths providing electron flow to or from said region, each path having a conductance which varies as a function of electron energy therein, means for applying an external potential to one or both of the conductance paths, and means for sensing a potential developed in said region.

2. An electronic device comprising a region providing ballistic electron flow, and at least first, second and third conductance paths providing electron flow to or from said region, each conductance path having a conductance which varies as a function of the energy of electrons therein, means for applying an external potential to one or more of the conductance paths, and means for sensing a potential, or a parameter relating to potential, at one or more of the conductance paths.

3. A device according to claim 1 or 2, wherein the external potential is a voltage or electrochemical potential.

4. A device according to any preceding claim, wherein the sensed potential is a voltage or electrochemical potential, or the sensed parameter is an electric current.

5. A device according to any preceding claim, wherein one or more conductance paths comprise conductance paths formed in areas providing ballistic electron flow.

6. A device according to claim 5, wherein said areas are comprised in said region.

7. A device according to any of claims 1 to 4, wherein one or more of the conductance paths includes a quantum point contact, narrow wire, resonant tunnelling device, or quantum dot.

8. A device according to any preceding claim, wherein each conductance path has an associated local reservoir of electrons, remote from said region and defining a local electrochemical potential.

9. A device according to claim 8, wherein said reservoir is associated with an electrical contact for the device.

10. A device according to claim 2, or any claim appendant thereto, wherein each conductance path (i,j=l,r,c) has an associated local reservoir having a respective electrochemical potential μ and wherein the current I in the third conductance path c is given by:
$${I}_{c} = \frac{2 ⅇ}{h} \{ \int [ {N}_{c} ( E ) - {R}_{cc} ( E ) ] f ( E - {μ}_{c} , T ) ⅆ E - {\sum }_{i = l , r} \int {T}_{ci} ( E ) f ( E - {μ}_{i} , T ) ⅆ E \}$$
where N_{c} is the number of quantum channels (occupied subbands) in the conductance path, μₗ and μᵣ are the electrochemical potentials in the left and right reservoirs, T the temperature at the reservoirs, and f (E−μ_{c,}T) the Fermi-Dirac function.

11. A device according to claim 8, wherein said device is symmetric with the first and second conductance paths forming symmetric left and rights paths (l, r) on either side of the third conductance path forming a central path (c).

12. An electronic device according to claim 2 or any claim appendant thereto, wherein the first, second and third conductance paths have respective conductance G(E) and a respective electro-chemical potential μ, wherein
$$\int {G}_{c} ( E ) f ( E - {μ}_{c} , T ) ⅆ E = \frac{1}{2} \int {G}_{c} ( E ) f ( E - {μ}_{l} , T ) ⅆ E + \frac{1}{2} \int {G}_{c} ( E ) f ( E - {μ}_{r} , T ) ⅆ E$$
where f is the Fermi-Dirac function.

13. A device according to claim 10, wherein for a voltage of magnitude V applied to the left and/or right paths, the voltage V_{c} at the third central conductance path is
$$a . {V}_{c} = - \frac{1}{2} α {V}^{2} + O ( {V}^{4} )$$
b. where μ_{c}−μ_{F}=−eV_{c}; μₗ−μ_{F}=−eV; and μᵣ−μ_{F}=eV.

14. A device according to any preceding claim, wherein the conductance of each said path is given by:
$$G ( E ) = \frac{2 {ⅇ}^{2}}{h} T ( E ) = \frac{2 {ⅇ}^{2}}{h} {\sum }_{m , n} {T}_{mn} ( E ) ,$$
wherein
$${T}_{mn} ( E ) = {δ}_{mn} \frac{1}{1 + {ⅇ}^{{πϵ}_{n}}} .$$

15. A device as claimed in any preceding claim, wherein the non-linear relationship is parabolic, or generally parabolic at small magnitudes of the applied voltage V.

16. An electronic device according to claim 1, wherein said region provides a stem or spur wherein the stem or spur is disposed in proximity to a further conductance path in a further electron flow path, in order to provide a probe to influence the conduction of electrons in the further flow path, whereby to achieve amplification.

17. An electronic device according to claim 6, wherein at least one of the paths is formed by etching in said region.

18. An electronic device consisting of a region providing ballistic electron flow, and at least first and second conductance paths for electron flow to or from said region which are such that there exists for each path a reservoir of electrons, or a contact, in at least temporary local equilibrium defining a local electrochemical potential, and means for applying first and second voltages to said first and second paths, the first and second paths being such that the conductance value for electron flow through each of the first and second paths is dependent upon the applied voltage, whereby to create a non-linear rectifying or transistor action for electron flow through said paths.

19. An electronic device consisting of a region providing ballistic electron flow, and at least first, second and third conductance paths for electron flow to or from said region which are such that there exists for each path a reservoir of electrons, or a contact, in at least temporary local equilibrium defining a local electrochemical potential, and means for applying first and second voltages to said first and second paths, the first and second paths being such that the conductance value for electron flow through each of the first and second paths is dependent upon the applied voltage, whereby to create a non-linear rectifying or transistor action for electron flow through said paths.

20. An electronic device according to any preceding claim, wherein at least one of the paths has a respective ohmic contact for conducting electrons and for applying external potential, and at which a local reservoir of electrons is formed.

21. An electronic device according to any preceding claim, wherein the means for applying or sensing a potential includes one or more gates, disposed adjacent to but electrically insulated from one or more conductance paths.

22. An electronic device according to claim 2, including means for applying an alternating voltage across the first and second paths, and means for monitoring a rectified voltage at the third path.

23. An electronic device according claim 2, including means for applying a voltage at the second path, and means for monitoring the relation between the voltage applied at the first path and the voltage developed at the third port in response to electron flow there through.

24. A method of achieving transistor action in an electronic device, the method comprising, providing a region having ballistic transport properties for electron flow, providing first, second and third conductance paths in said region which provide electron flow to or from said region, each path having a conductance which is a function of the electron energy in the path, and applying a voltage to one or more of the paths in order to modulate the characteristics of electron flow through the other two paths in a non-linear manner.

25. A method of rectifying an alternating voltage, comprising providing a region having ballistic transport properties for electron flow, and providing first, second and third conductance paths for electron flow to and from said region, each path having a conductance dependent on energies of electrons passing through the path, and applying an alternating voltage across two of the paths, and deriving a rectified voltage from the third path.

26. An electronic device according to any of claims 2 to 22, wherein the first, second and third paths are connected so as to provide a logical AND or OR function.

27. An electronic device according to any of claims 1 to 23, wherein the first, second and third paths are connected to receive an alternating voltage of certain frequencies across one or more of the ports, and to generate a sum and/or a harmonic of the frequencies at one or more further paths of the device.

28. An electronic device comprising first, second and third terminals, each terminal including an electrical contact connected by a respective conductance path providing electron flow to a central region of ballistic electron flow, the arrangement being such that an alternating voltage applied to the first and second terminals provides a rectified voltage at the third terminal.

29. An electronic device comprising first, second and third terminals, each terminal including an electrical contact connected by a respective conductance path providing electron flow to a central region of ballistic electron flow, the arrangement being such that applying a voltage to one terminal, modulates the characteristics of electron flow through the other two terminals in a non-linear manner.

30. An electronic logic device comprising first, second and third terminals, each terminal including an electrical contact connected by a respective conductance path providing electron flow to a central region of ballistic electron flow, the arrangement being such that input signal potentials applied to first and second terminals provide an output signal potential at the third terminal according to a pre-determined logic function.

31. An electronic logic device comprising first, second and third terminals, each terminal including an electrical contact connected by a respective conductance path providing electron flow to a central region of ballistic electron flow, the arrangement being such that input signal potentials applied to first and second terminals provide an output signal potential at the third terminal according to an AND or OR logic function..

32. A device according to claim 30 or 31, wherein the electric power for operating the device is provided from the power in the input signals comprising the external potentials applied to the first and second terminals.

33. A device according to claim 30 or 31, wherein the device is symmetric such that said input signals may be applied to any two of the first, second and third terminals and said output signal taken from the remaining terminal.

34. A logic circuit including a device according to claim 30 or 31, wherein the output signal is provided to a second device, similar to that of claim 30 or 31, for providing a signal level translation.

35. A circuit according to claim 34, wherein the second device has a first terminal couple to receive the output signal , a second terminal coupled to a ground reference signal, and a third terminal for providing an output signal.

36. A logic circuit including a device according to claim 30 or 31, wherein the output signal is provided to a second device, for providing a NAND function, the second device comprising first, second and third terminals, each terminal including an electrical contact connected by a respective conductance path providing electron flow to a central region of ballistic electron flow, and a gate for influencing the characteristics of one of the conductance paths, said output signal being applied to the gate to provide an inverted version of the output signal at a terminal of the second device.

37. A circuit according to claim 36, wherein the other terminals of the second device are connected between a voltage supply rail and reference potential.

38. A device according to claim 30 or 31, wherein at least one of the conductive paths is coupled to a gate to which an external potential may be applied for adjusting the conductive characteristics of the conductive path.
